(19) United States
(12) Patent Application Publication
(10) Pub. No.: US 2025/0167112 A1
(43) Pub. Date: May 22, 2025

(54) MEMORY DEVICE AND METHOD OF MANUFACTURING MEMORY DEVICE

(71) Applicant: SAMSUNG ELECTRONICS CO., LTD., Suwon-si (KR)

(72) Inventors: Jungwon Choe, Suwon-si (KR); Changbum Kim, Suwon-si (KR); Sunghoon Kim, Suwon-si (KR)

(21) Appl. No.: 18/745,755

(22) Filed: Jun. 17, 2024

(30) Foreign Application Priority Data
Nov. 21, 2023 (KR) 10-2023-0161774

(51) Int. Cl. H01L 23/528; H01L 23/522; H10B 41/10; H10B 41/27; H10B 41/40; H10B 43/10; H10B 43/27; H10B 43/40

(52) U.S. Cl. CPC H01L 23/5283; H01L 23/5226; H01L 23/528; H10B 41/10; H10B 41/27; H10B 41/40; H10B 43/10; H10B 43/27; H10B 43/40

(57) ABSTRACT

An example memory device includes a lower interconnection structure on a substrate, a cell stack structure on the lower interconnection structure, an interlayer insulating layer covering the cell stack structure, an upper interconnection structure on the interlayer insulating layer, one or more effective contact structures respectively passing through the interlayer insulating layer, and one or more preliminary contact structures respectively passing through the interlayer insulating layer. The lower interconnection structure includes circuit components and lower conductive patterns. The cell stack structure includes gate electrodes stacked and spaced apart from each other in a vertical direction. The vertical direction is perpendicular to an upper surface of the substrate. The upper interconnection structure includes upper conductive patterns and one or more external pads. The one or more preliminary contact structures are electrically floating.

### CROSS-REFERENCE TO RELATED APPLICATION

This application claims benefit of priority to Korean Patent Application No. 10-2023-0161774 filed on Nov. 21, 2023, in the Korean Intellectual Property Office, the disclosure of which is incorporated herein by reference in its entirety.

### BACKGROUND

Recently, a vertical memory device has been developed in which a peripheral circuit is formed on a substrate and a memory cell is vertically disposed on the peripheral circuit. The vertical memory device may include a through-via contact structure passing through an interlayer insulating film covering the memory cell, the through-via structure in contact with an interconnection of the peripheral circuit.

### SUMMARY

An aspect of the present disclosure relates to a memory device having improved utility by allowing the number or positions of effective contact structures of a vertical memory device to be easily changed.

Another aspect of the present disclosure relates to a semiconductor device in which defects in an effective contact structure are reduced.

Another aspect of the present disclosure relates to a method of manufacturing a vertical memory device, the method capable of reducing time and costs required for manufacturing.

In general, according to some aspects, a memory device includes a lower interconnection structure provided on a substrate, the lower interconnection structure including circuit components and lower conductive patterns, a cell stack structure provided on the lower interconnection structure, the cell stack structure including gate electrodes stacked to be spaced apart from each other in a vertical direction, perpendicular to an upper surface of the substrate, an interlayer insulating layer covering the cell stack structure, an upper interconnection structure provided on the interlayer insulating layer, the upper interconnection structure including upper conductive patterns and one or more external pads, externally exposed, one or more effective contact structures respectively passing through the interlayer insulating layer, the one or more effective contact structures respectively having an upper surface in contact with a first upper pad electrically connected to one of the one or more external pads, and a lower surface in contact with a first lower pad electrically connected to the circuit components, and one or more preliminary contact structures respectively passing through the interlayer insulating layer, the one or more preliminary contact structures respectively having an upper surface in contact with a second upper pad, and a lower surface in contact with a second lower pad. The one or more preliminary contact structures may be electrically floating.

In general, according to some aspects, a memory device includes a lower interconnection structure provided on a substrate, the lower interconnection structure including circuit components and lower conductive patterns, a cell stack structure provided on the lower interconnection structure, the cell stack structure including gate electrodes stacked to be spaced apart from each other in a vertical direction, perpendicular to an upper surface of the substrate, an interlayer insulating layer covering the cell stack structure, an upper interconnection structure provided on the interlayer insulating layer, the upper interconnection structure including upper conductive patterns and an external pad exposed externally, an effective contact structure passing through the interlayer insulating layer, the effective contact structure having an upper surface in contact with a first upper pad electrically connected to the external pad, and a lower surface in contact with a first lower pad electrically connected to the circuit components, and one or more preliminary contact structures respectively passing through the interlayer insulating layer, the one or more preliminary contact structures respectively having a structure the same as that of the effective contact structure. The one or more preliminary contact structures may be electrically floating.

In general, according to some aspects, a memory device includes a lower chip including a first substrate, circuit components disposed on the first substrate, and a lower interconnection structure electrically connected to the circuit components, and an upper chip disposed on the lower chip, the upper chip including a second substrate, an upper interconnection structure disposed on an upper surface of the second substrate, an external pad connected to the upper interconnection structure, a cell stack structure including gate electrodes stacked to be spaced apart from each other in a first direction, perpendicular to a lower surface of the second substrate, an interlayer insulating layer surrounding a lower surface and a side surface of the cell stack structure, an intermediate interconnection structure disposed below the interlayer insulating layer and bonded to the lower interconnection structure, one or more effective contact structures respectively passing through the interlayer insulating layer, the one or more effective contact structures respectively having an upper surface in contact with a first upper pad electrically connected to the external pad, and a lower surface in contact with a first lower pad electrically connected to the circuit components, and one or more preliminary contact structures respectively passing through the interlayer insulating layer, the one or more preliminary contact structures respectively having an upper surface in contact with a second upper pad, and a lower surface in contact with a second lower pad.

The one or more preliminary contact structures may be electrically floating.

In general, according to some aspects, a method of manufacturing a memory device includes generating a layout of the memory device including a lower interconnection structure, a cell stack structure provided on the lower interconnection structure, an interlayer insulating layer covering the cell stack structure, an upper interconnection structure provided on the interlayer insulating layer, and a plurality of contact structures passing through the interlayer insulating layer, manufacturing, based on the layout, a plurality of masks, modifying the number or positions of effective contact structures electrically connected to the lower interconnection structure and the upper interconnection structure, among the plurality of contact structures, changing an effective contact structure, among the plurality of contact structures, by modifying, based on the modified number or positions of the effective contact structures, a mask corresponding to the lower interconnection structure or the upper interconnection structure, and completing the memory device using the plurality of masks including the modified mask.

### BRIEF DESCRIPTION OF THE DRAWINGS

The above and other aspects, features, and advantages of the present disclosure will be more clearly understood from the following detailed description, taken in conjunction with the accompanying drawings.

FIGS. 1A, 1B, and 2 are diagrams illustrating an example of a memory device.

FIGS. 3 to 11 are diagrams illustrating an example of a method of manufacturing a vertical memory device.

FIGS. 12 to 14 are diagrams illustrating an example of a vertical memory device.

FIG. 15 is a cross-sectional view illustrating an example of a memory device.

FIG. 16 is a flowchart illustrating an example of a method of manufacturing a memory device.

### DETAILED DESCRIPTION

Hereinafter, example implementations of the present disclosure will be described with reference to the attached drawings.

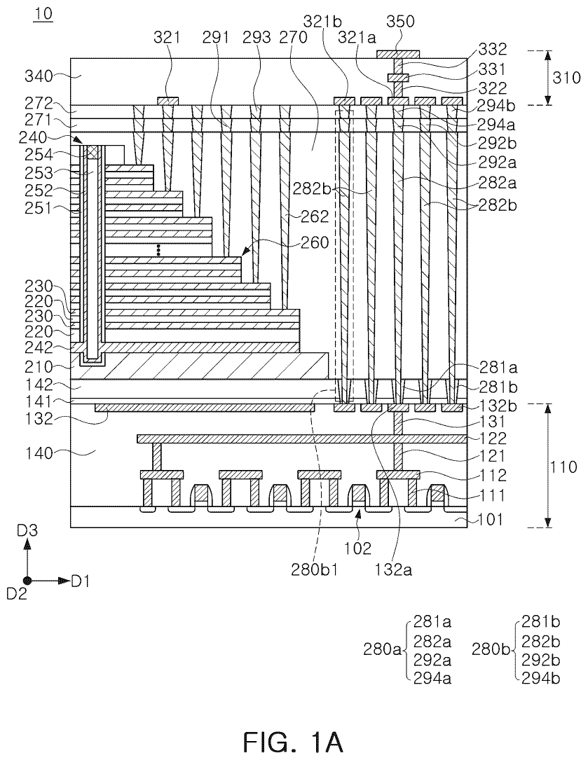

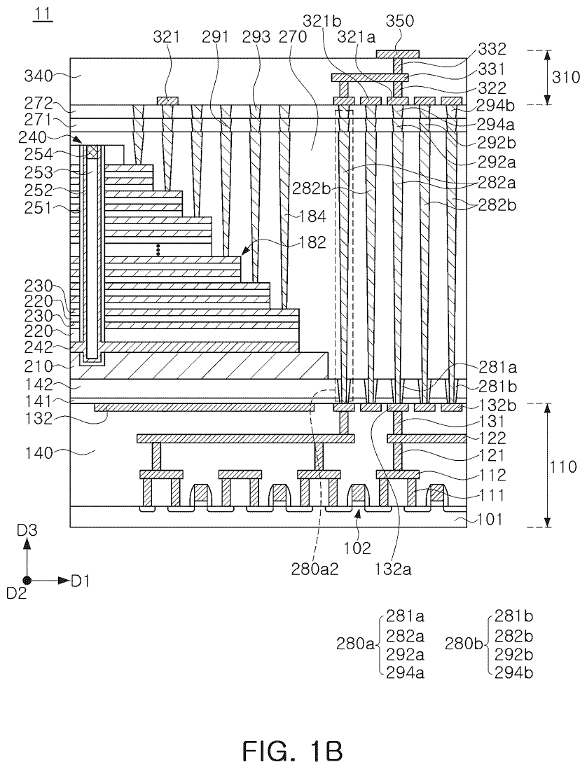

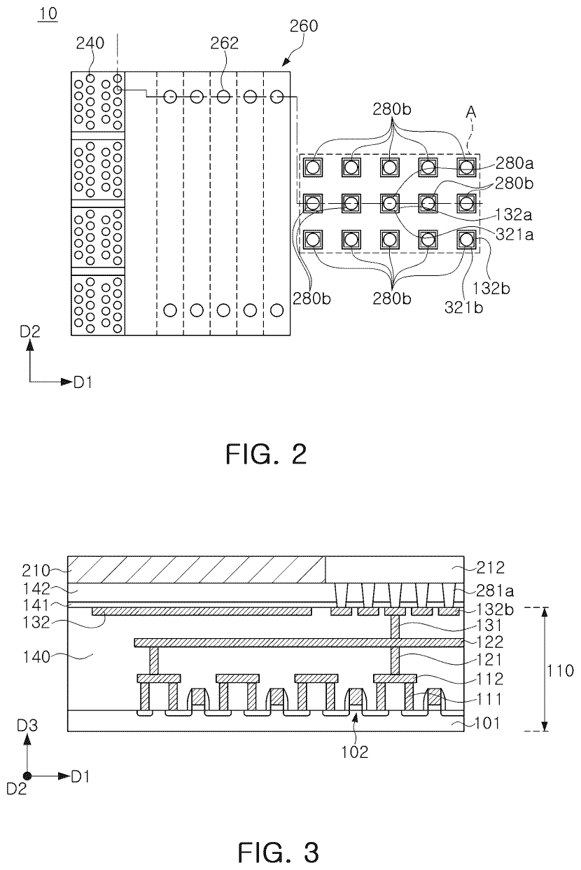

FIGS. 1A, 1B, and 2 are diagrams illustrating an example of a memory device. FIG. 2 is a plan view illustrating an example of a memory device, and FIGS. 1A and 1B are cross-sectional views illustrating exemplary cross-sections taken along line I-I′ of FIG. 2.

Referring to FIG. 1A, a memory device 10 may include a circuit pattern formed on a substrate 101, a cell stack structure 260 formed on the circuit pattern, a channel structure 240, a cell contact plug 262, and through-hole vias 282a and 282b.

The substrate 101 may include a semiconductor material such as silicon, germanium, or silicon-germanium, or a group III-V compound such as GaP, GaAs, or GaSb. In some implementations, the substrate 101 may be a silicon-on-insulator (SOI) substrate or a germanium-on-insulator (GOI) substrate.

A lower interconnection structure 110 included in a peripheral circuit, driving a memory cell, may be formed on the substrate 101. The lower interconnection structure 110 may include circuit components 102, lower contact plugs 111, 121, and 131, and lower conductive patterns 112, 122, and 132. A first lower interlayer insulating film 140 may be provided on the substrate 101 to cover the lower interconnection structure 110. The lower contact plugs 111, 121, and 131 and the lower conductive patterns 112, 122, and 132 may be electrically connected to the circuit components 102, for example, transistors.

In some implementations, the lower contact plugs 111, 121, and 131 and the lower conductive patterns 112, 122, and 132 may be formed in multiple layers. In the example of FIG. 1A, the third lower conductive patterns 132 may be an uppermost interconnection, among lower interconnections formed below a base semiconductor pattern 210. Upper surfaces of the third lower conductive patterns 132 and an upper surface of the first lower interlayer insulating film 140 may be coplanar with each other.

At least a portion of the third lower conductive patterns 132 may be provided as pad patterns 132a and 132b in contact with lower surfaces of the through-hole vias 282a and 282b. The pad patterns 132a and 132b may overlap the through-hole vias 282a and 282b in a vertical direction. In some implementations, the pad pattern 132a and the through-hole via 282a may be in contact with each other, such that the circuit components 102 and upper interconnections may be electrically connected to each other.

In some implementations, the circuit components 102 may be connected to each other in series or parallel by a first lower contact plug 111 and a first lower conductive pattern 112. In addition, the circuit components 102, connected to each other, may be controlled by a voltage applied from the through-hole via 282a to the first lower conductive pattern 112 through the pad pattern 132a.

An etch stop film 141 may be provided on the third lower conductive patterns 132 and the first lower interlayer insulating film 140. The etch stop film 141 may include silicon nitride. A second lower interlayer insulating film 142 may be provided on the etch stop film 141.

One or more base semiconductor patterns 210 may be provided on the second lower interlayer insulating film 142. In some implementations, the base semiconductor pattern 210 may include a polysilicon layer or single crystal silicon. The base semiconductor pattern 210 may overlap a region in which the cell stack structure 260 is to be formed in the vertical direction.

A lower conductive pattern may be provided on a lower surface of the base semiconductor pattern 210. The lower conductive pattern may include a metal or metal silicide. The lower conductive pattern may be provided as a common source line CSL.

The cell stack structure 260, including a plurality of memory cells, may be provided on the base semiconductor pattern 210. In some implementations, the memory device 10 may include a plurality of cell stack structures. For example, a plurality of cell stack structures 260 may be disposed to be parallel to each other in at least one direction while being spaced apart from each other. However, FIGS. 1A and 2 illustrate only one cell stack structure 260 included in the memory device 10.

An edge portion of the cell stack structure 260 may have a staircase shape. A portion of the cell stack structure 260, having a staircase shape, may be referred to as a pad region, and a portion of the cell stack structure 260, not having a staircase shape, may be referred to as a cell region.

The cell stack structure 260 may include a channel connection pattern 242, a plurality of gate electrodes 230, and a plurality of insulating patterns 220. The plurality of gate electrodes 230 and the plurality of insulating patterns 220 may be alternately disposed on an upper portion of the channel connection pattern 242 in the vertical direction.

The plurality of gate electrodes 230 may include a metal material. The plurality of gate electrodes 230 may include a barrier pattern and a metal pattern. For example, the metal pattern may include a metal having low electrical resistance, such as tungsten, titanium, tantalum, platinum, or cobalt, and the barrier pattern may include a metal nitride, such as titanium nitride or tantalum nitride.

The channel structure 240 may be provided in the cell region of the cell stack structure 260 to pass through the gate electrodes 230 and the insulating patterns 220. The channel structure 240 may include a charge storage structure 251, a channel 252, a buried insulating pattern 253, and a capping pattern 254. The charge storage structure 251 may include a blocking pattern, a charge storage pattern, and a tunnel insulating pattern, sequentially stacked.

In some implementations, the channel structure 240 may pass through the gate electrodes 230 and the insulating patterns 220 and extend to the inside of the base semiconductor pattern 210. The charge storage structure 251 may have a cut-out shape at a portion of the channel connection pattern 242. A sidewall of the channel 252 may be in contact with the channel connection pattern 242. Accordingly, the channel 252 may be electrically connected to the base semiconductor pattern 210 through the channel connection pattern 242.

Edge portions of the gate electrodes 230 included in the pad region of the cell stack structure 260 may be positioned on different planes, that is, on different layers.

Cell contact plugs 262 may be provided to pass through a first intermediate interlayer insulating film 270, disposed on the pad region of the cell stack structure 260, and to be in contact with an upper edge portion of the gate electrode 230. The cell contact plugs 262 may have different vertical heights.

The first intermediate interlayer insulating film 270 may be provided to cover the cell stack structure 260, the base semiconductor pattern 210, and the second lower interlayer insulating film 142. The first intermediate interlayer insulating film 270 may have a substantially flat upper surface. Accordingly, a vertical thickness of the first intermediate interlayer insulating film 270, disposed on the pad region of the cell stack structure 260, may be greater than a vertical thickness of the first intermediate interlayer insulating film 270, disposed on the cell region of the cell stack structure 260. In addition, a vertical thickness of the first intermediate interlayer insulating film 270, disposed on the second lower interlayer insulating film 142, may be greater than the vertical thickness of the first intermediate interlayer insulating film 270, disposed on the pad region of the cell stack structure 260.

The contact through-hole via 282a may be provided around the cell stack structure 260 to pass through the first intermediate interlayer insulating film 270, and the second lower interlayer insulating film 142 and the etch stop film 141 therebelow, and to be in contact with the third lower conductive pattern 132. In some implementations, a lower via 281a may be provided to pass through the etch stop film 141 and the second lower interlayer insulating film 142, and the through-hole via 282a may be formed to pass through the lower via 281a.

A second intermediate interlayer insulating film 271 may be provided on the first intermediate interlayer insulating film 270. A first cell contact 291 and a first peripheral contact 292a may be provided to pass through the second intermediate interlayer insulating film 271. The first cell contact 291 may be in contact with an upper surface of the cell contact plug 262, and the first peripheral contact 292a may be in contact with an upper surface of the through-hole via 282a.

A third intermediate interlayer insulating film 272 may be provided on the second intermediate interlayer insulating film 271. A second cell contact 293 and a second peripheral contact 294a may be provided to pass through the third intermediate interlayer insulating film 272. The second cell contact 293 may be in contact with an upper surface of the first cell contact 291, and the second peripheral contact 294a may be in contact with an upper surface of the first peripheral contact 292a.

In the example of FIG. 1A, a structure may be in which two upper contacts are vertically stacked on upper portions of the cell contact plug 262 and the through-hole via 282a. However, in the present disclosure, the number of upper contacts stacked on the upper portions of the cell contact plug 262 and the through-hole via 282a is not limited thereto.

The lower via 281a, the through-hole via 282a, the first peripheral contact 292a, and the second peripheral contact 294a may be collectively referred to as a contact structure 280a.

An upper interconnection structure 310 may be provided on the third intermediate interlayer insulating film 272 to provide an external signal to the second cell contact 293 and the second peripheral contact 294a.

The upper interconnection structure 310 may include upper conductive patterns 321 and 331, upper contact plugs 322 and 332, and an external pad 350. The upper conductive patterns 321 and 331 and the upper contact plugs 322 and 332 may be electrically connected to the cell contact plug 262 and the contact structure 280a.

In addition, the upper conductive patterns 321 and 331 and the upper contact plugs 322 and 332 may connect the contact structure 280a to the external pad 350 to supply externally received power to a peripheral circuit, to provide an externally received signal to the peripheral circuit, or to externally output a signal generated from the peripheral circuit. For example, a first upper conductive pattern 321a may be in contact with an upper surface of the second contact structure 280a. The first upper conductive pattern 321a may function as a pad pattern of the second contact structure 280a. The pad pattern 321a may be electrically connected to the external pad 350 through a first contact plug 322, a second upper conductive pattern 331, and a second contact plug 332.

In order to generate a semiconductor device, multiple processes may need to be performed on the substrate 101. In order to complete a single semiconductor device, multiple processes may be performed over several months. For example, while a preceding process of forming the circuit components 102 on the substrate 101 is performed, interconnections of the lower interconnection structure 110 and the upper interconnection structure 310 may be designed to connect the circuit components 102 to each other. In addition, the memory device 10 may be completed by forming the designed interconnections in a subsequent process.

While the memory device 10 is designed, an interconnection of the memory device 10 may be modified. As the interconnections of the lower interconnection structure 110 and the upper interconnection structure 310 are modified, the number or positions of contact structures 280a for electrically connecting the lower interconnection structure 110 and the upper interconnection structure 310 to each other may be changed.

The contact structure 280a may include the lower via 281a, the through-hole via 282a, and the first and second peripheral contacts 292a and 294a, formed over multiple layers including the etch stop film 141, the second lower interlayer insulating film 142, the first intermediate interlayer insulating film 270, and the first and second upper interlayer insulating films 271 and 272. Semiconductor masks respectively corresponding to the multiple layers may be used to form the memory device 10.

When the semiconductor masks, respectively corresponding to the multiple layers, need to be modified to change the number or positions of contact structures 280a, time and costs required for designing the memory device 10 may be increased.

In some implementations, the memory device 10 may include a plurality of contact structures 280b provided around the contact structure 280a. Each of the plurality of contact structures 280b may have a structure substantially the same as that of the contact structure 280a. In the example of FIG. 1A, each of the plurality of contact structures 280b may include a lower via 281b, a through-hole via 282b, a first peripheral contact 292b, and a second peripheral contact 294b.

In the same manner as the pad pattern 132a being in contact with a lower surface of the contact structure 280a and the pad pattern 321a being in contact with an upper surface of the contact structure 280a, the pad pattern 132b may be in contact with a lower surface of each of the plurality of contact structures 280b, and a pad pattern 321b may be in contact with an upper surface of each of the plurality of contact structures 280b. Hereinafter, the pad pattern 132a and the pad pattern 321a may be referred to as a first lower pad and a first upper pad, respectively. In addition, the pad pattern 132b and the pad pattern 321b may be referred to as a second lower pad and a second upper pad, respectively.

In a different manner from the contact structure 280a being electrically connected to the circuit component 102 through a first lower pad 132a and being electrically connected to the external contact 350 through a first upper pad 321a, the plurality of contact structures 280b may be electrically floating. That is, the plurality of contact structures 280b may not be electrically connected to the circuit component 102 and the external contact 350. The contact structure 280a may be referred to as an effective contact structure, and the contact structure 280b may be referred to as a preliminary contact structure.

Preliminary contact structures 280b may not be involved in electrically driving memory cells, but the preliminary contact structures 280b may have a structure the same as that of an effective contact structure 280a over multiple layers including the etch stop film 141, the second lower interlayer insulating film 142, the first intermediate interlayer insulating film 270, and the first and second upper interlayer insulating films 271 and 272.

In addition, the preliminary contact structures 280b may be in contact with a second lower pad 132b and a second upper pad 321b. Accordingly, when the circuit component 102 is electrically connected to the second lower pad 132b and the external pad 350 is electrically connected to the second upper pad 321b by modifying the interconnections included in the lower interconnection structure 110 and the upper interconnection structure 310, the preliminary contact structures 280b may be used as effective contact structures.

In some implementations, time and costs required for changing the number or positions of effective contact structures 280a of the semiconductor device 10 may be reduced.

FIG. 1B illustrates a memory device 11 in which the number of effective contact structures 280a is changed, as compared to FIG. 1A.

When comparing FIGS. 1A and 1B to each other, a first contact structure 280b1 of FIG. 1A and a second contact structure 280a2 of FIG. 1B may be disposed in the same positions of the memory devices 10 and 11, respectively, and may have substantially the same structure.

Upper and lower pads in contact with the first contact structure 280b1 may be electrically floating, and the first contact structure 280b1 may be provided as a preliminary contact structure 280b. Conversely, an upper pad in contact with the second contact structure 280a2 may be electrically connected to the external pad 350, and a lower pad in contact with the second contact structure 280a2 may be electrically connected to the circuit component 102. Accordingly, the second contact structure 280a2 may function as the effective contact structure 280a.

In some implementations, the number or positions of effective contact structures 280a, among contact structures, may be changed by modifying only semiconductor masks corresponding to the lower interconnection structure 110 and the upper interconnection structure 310, without modifying semiconductor masks respectively corresponding to multiple layers including the contact structures 280a and 280b.

In addition, defects in the effective contact structure 280a of the memory device may be prevented.

Referring to FIG. 2, the effective contact structure 280a and the preliminary contact structures 280b may be arranged in a first direction D1, parallel to an upper surface of the substrate 101, and a second direction D2, parallel to the upper surface of the substrate 101 and intersecting the first direction D1. In some implementations, contact structures adjacent to each other, among the contact structures 280a and 280b, may be spaced apart from each other by a predetermined distance.

The effective contact structure 280a and the plurality of preliminary contact structures 280b, disposed to be adjacent to each other, may prevent not-opening defects in the through-hole via 282a. Specifically, when the memory device 10 is manufactured, a plasma etching process may be performed to form a through-via hole in a position in which the through-hole via 282a is disposed.

When a single through-via hole is formed in an isolated position, inlets through which etching gas flows may be small in number and may have a small area, such that it may be difficult for the etching gas to uniformly flow into a lower surface portion of the through-via hole. When the etching gas does not uniformly flow into the lower surface portion of the through-via hole, not-opening defects may occur in which the first lower pad 132a is not exposed to a lower surface of the through-via hole.

Conversely, etching gas may flow into a position in which each of the through-hole via 282a and the through-hole vias 282b is to be formed in a plasma etching process. Accordingly, the number and area of inlets through which the etching gas flows may be increased, and the etching gas may uniformly flow into lower surface portions of the through-hole via 282a and the through-hole vias 282b. Accordingly, not-opening defects in the through-hole via 282a and through-hole vias 282b may be reduced.

FIGS. 3 to 11 are diagrams illustrating an example of a method of manufacturing a vertical memory device.

Referring to FIG. 3, a lower interconnection structure 110 included in a peripheral circuit may be formed on a substrate 101, and a first lower interlayer insulating film 140 may be formed to cover the lower interconnection structure 110. The lower interconnection structure 110 may include circuit components 102, lower contact plugs 111, 121, and 131, and lower conductive patterns 112, 122, and 132.

Uppermost third lower conductive patterns 132, among lower contact plugs, may include a first lower pad 132a and a second lower pad 132b. The first lower pad 132a may be connected to the circuit component 102 through the lower conductive patterns 112 and 122. Conversely, the second lower pad 132b may not be connected to the lower conductive patterns 112 and 122 but may be separated from the circuit component 102 by the first lower interlayer insulating film 140.

The number and positions of first lower pads 132a may be determined depending on a connection structure between the circuit components 102 included in the peripheral circuit. In some implementations, the number and positions of lower pads may be fixed while the peripheral circuit is designed, and the number and positions of first lower pads 132a may be modified by changing a connection structure between the lower pads and the lower conductive patterns 112 and 122.

An etch stop film 141 and a second lower interlayer insulating film 142 may be formed on the first lower interlayer insulating film 140. A base semiconductor pattern 210 may be formed on the second lower interlayer insulating film 142. A first insulating film pattern 212 may be formed between the base semiconductor patterns 210. Upper surfaces of the base semiconductor pattern 210 and the first insulating film pattern 212 may be positioned on the same plane.

A plurality of lower vias 281a may be formed to pass through the etch stop film 141 and the second lower interlayer insulating film 142. The plurality of lower vias 281a may be in contact with upper surfaces of the lower pads 132a and 132b.

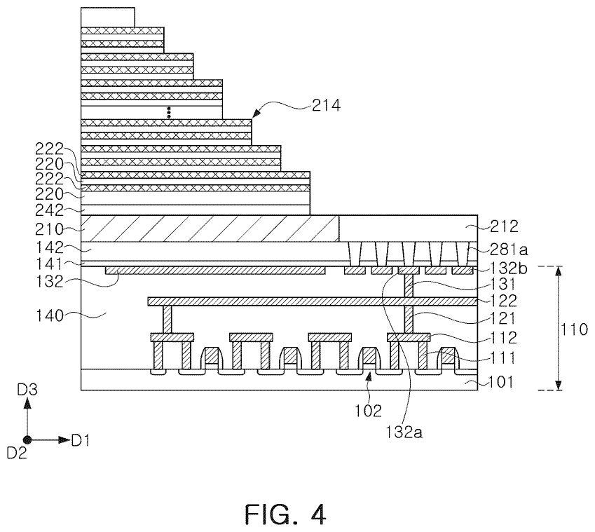

Referring to FIG. 4, sacrificial films and insulating films may be alternately stacked on a base semiconductor pattern 210 and a first insulating film pattern 212. The insulating films may include silicon oxide. The sacrificial films may include a material having an etch selectivity due to the insulating films, for example, nitride such as silicon nitride. A lower sacrificial film may be formed on a lowermost portion in contact with an upper surface of the base semiconductor pattern 210. A mold structure 214 may be formed by stacking the sacrificial films and the insulating films.

The mold structure 214 may be formed on the base semiconductor pattern 210. A lowermost sacrificial pattern 241 may be provided on a lowermost portion of the mold structure 214. An edge portion of the mold structure 214 in a first direction may have a staircase shape.

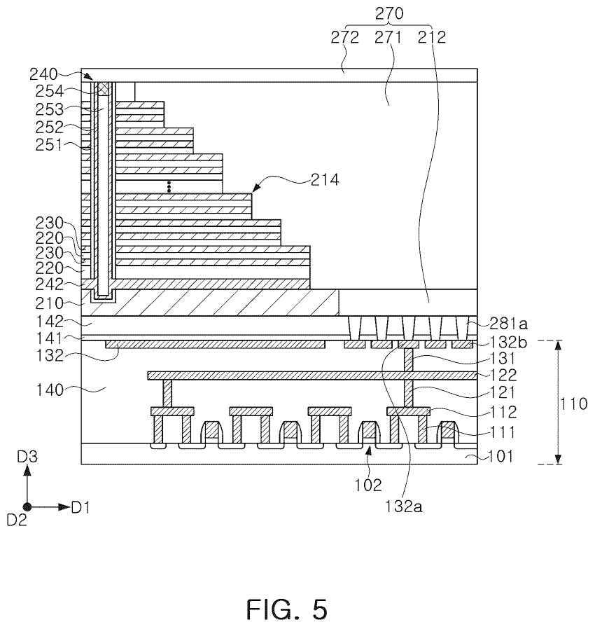

Referring to FIG. 5, a second insulating film 271 may be formed to cover a mold structure 214, a base semiconductor pattern 210, and a first insulating film pattern 212. An upper surface of the second insulating film 271 may be planarized using a planarization process. In addition, a third insulating film 272 may be formed on the second insulating film 271. A first insulating film pattern 212, the second insulating film 271, and the third insulating film 272 may include silicon oxide. The first insulating film pattern 212, the second insulating film 271, and the third insulating film 272 may include the same material, and may be collectively referred to as a first intermediate interlayer insulating film 270.

A preliminary channel structure may be formed to pass through a first interlayer insulating film 270 on an upper portion of the mold structure 214, and to extend to the base semiconductor pattern 210. The preliminary channel structure may include a preliminary charge storage structure, a channel 252, a buried insulating pattern 253, and a capping pattern 254.

A lowermost sacrificial pattern 241 of the mold structure 214 may be removed to form a gap, and the preliminary charge storage structure, exposed to a portion of the gap, may be removed to form a charge storage structure 251. A channel connection pattern 242 may be formed in the gap. For example, the channel connection pattern 242 may include polysilicon. The channel connection pattern 242 may be in contact with a sidewall of the channel 252, such that the channel 252 and the channel connection pattern 242 may be electrically connected to each other. In addition, the channel connection pattern 242 may be in contact with an upper surface of the base semiconductor pattern 210.

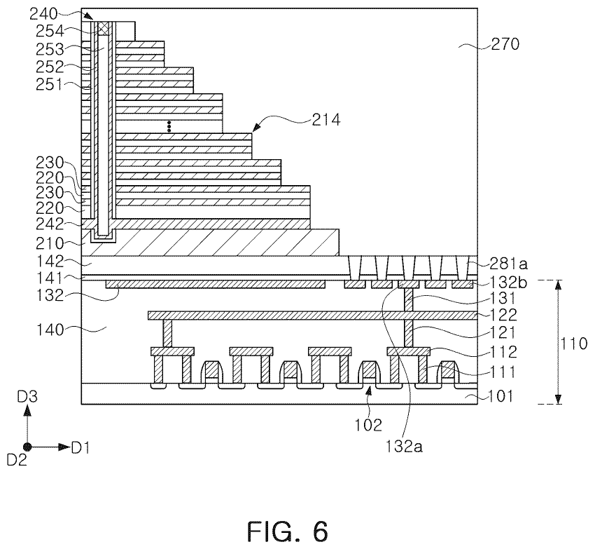

Referring to FIG. 6, respective sacrificial patterns 222 included in a mold structure 214 may be removed to form gaps between each of a plurality of insulating patterns 220. Gate electrodes 230 may be formed by filling the gaps with a conductive material.

The gate electrodes 230 may be formed on the mold structure 214, such that the mold structure 214 may be provided as a cell stack structure 260. The cell stack structure 260 may include a channel connection pattern 242, a plurality of gate electrodes 230 provided on the channel connection pattern 242, the plurality of gate electrodes 230 spaced apart from each other in a vertical direction, and insulating patterns 220 formed between the gate electrodes 230.

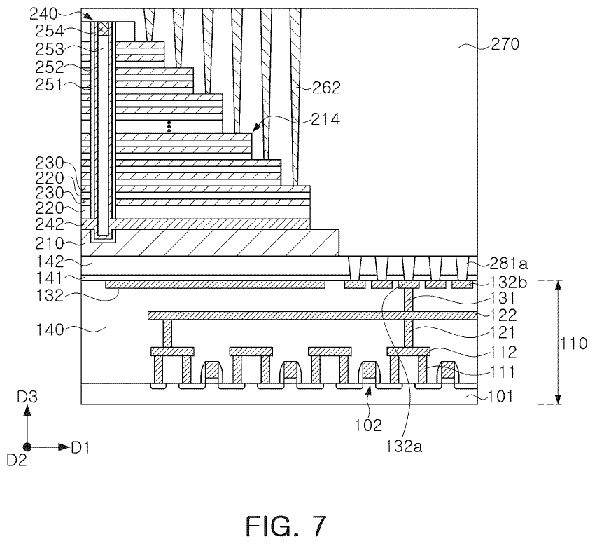

Referring to FIG. 7, first contact holes may be formed to pass through a first intermediate interlayer insulating film 270 positioned at an edge of the cell stack structure 260, and to expose an edge of a gate electrode 230. Cell contact plugs 262, respectively in contact with the gate electrodes 230, may be formed by filling the first contact holes with a conductive material.

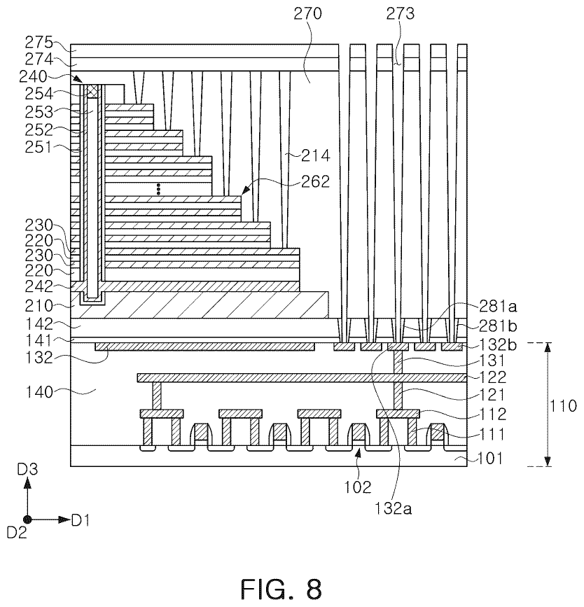

Referring to FIG. 8, a first intermediate interlayer insulating film 270 and a lower via 281a, positioned around a cell stack structure 260, may be sequentially etched to form through-via holes 273. The through-via holes 273 may be formed in positions overlapping those of lower pads 132a and 132b in a vertical direction.

For example, a hard mask 186 may be formed on the first intermediate interlayer insulating film 270, and a photoresist pattern 188 may be formed by coating a photoresist film on the hard mask 186 and performing a photographic process. The photoresist pattern 188 may have openings in positions in which the through-via holes 273 are to be formed.

A plurality of through-via holes 273 may be formed to be adjacent to each other. In some implementations, a total area of the openings of the photoresist pattern 188 may be increased, and etching gas may be smoothly introduced through the openings. The openings may be etched by the etching gas, such that through-via holes 273 may be formed, and upper surface portions of the lower pads 132a and 132b may be successfully exposed through the through-via holes 273. That is, an etching process may be performed on the plurality of adjacent through-via holes 273, thereby preventing not-opening defects in the through-via holes 273.

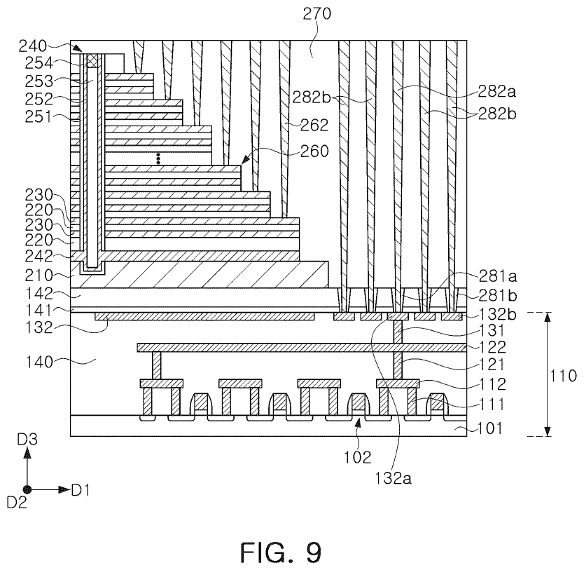

Referring to FIG. 9, through-hole vias 282a and 282b may be formed in through-via holes 273 by filling the through-via holes 273 with a conductive material. The through-hole vias 282a and 282b may include a barrier pattern and a metal pattern.

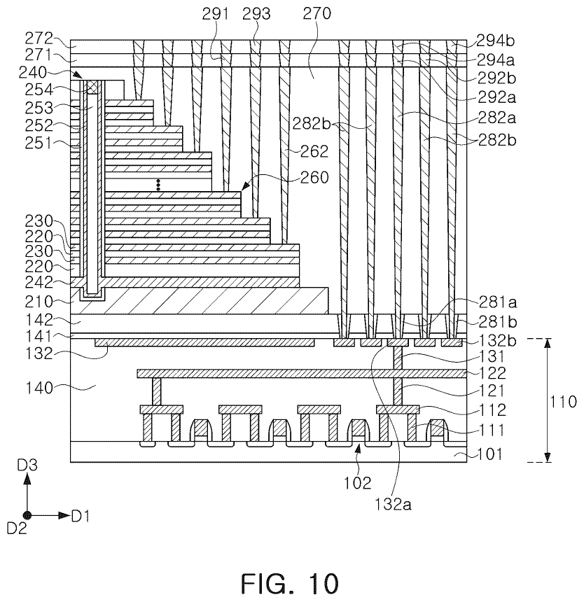

Referring to FIG. 10, a second intermediate interlayer insulating film 271 may be formed on a first intermediate interlayer insulating film 270. The second intermediate interlayer insulating film may be etched and filled with a conductive material, thereby forming a first cell contact 291 and first peripheral contacts 292a and 292b. The first cell contact 291 may be in contact with an upper surface of a cell contact plug 262, and the first peripheral contacts 292a and 292b may be in contact with upper surfaces of through-hole vias 282a and 282b.

A third intermediate interlayer insulating film 272 may be formed on the second intermediate interlayer insulating film 271. The third intermediate interlayer insulating film 272 may be etched and filled with a conductive material, thereby forming a second cell contact 293 and second peripheral contacts 294a and 294b. The second cell contact 293 may be in contact with an upper surface of the first cell contact 291, and the second peripheral contacts 294a and 294b may be in contact with upper surfaces of the first peripheral contacts 292a and 292b.

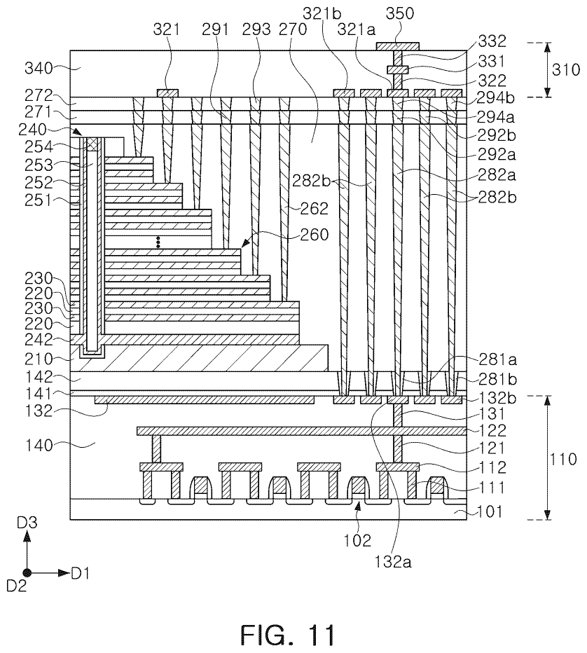

Referring to FIG. 11, an upper interconnection structure 310 may be formed on an upper surface of a third intermediate interlayer insulating film 272. The upper interconnection structure 310 may include upper conductive patterns 321 and 331, upper contact plugs 322 and 332, and an external pad 350, and the upper conductive patterns 321 and 331 and the upper contact plugs 322 and 332 may be surrounded by an upper interlayer insulating film 340.

For example, a first upper interlayer insulating film may be formed on the upper surface of the third intermediate interlayer insulating film 272, and the first upper interlayer insulating film may be etched and filled with a conductive material, thereby forming first upper conductive patterns 321. Similarly, a second upper interlayer insulating film on which first upper contact plugs 322 are formed, a third upper interlayer insulating film on which second upper conductive patterns 331 are formed, and a fourth upper interlayer insulating film on which second upper contact plugs 332 are formed may be sequentially stacked. The first to fourth upper interlayer insulating films may be collectively referred to as the upper interlayer insulating film 340. At least one external pad 350 may be formed on an upper surface of the upper interlayer insulating film 340.

The upper conductive patterns 321 may include a first upper pad 321a in contact with an upper surface of a second peripheral contact 294a, and a second upper pad 321b in contact with an upper surface of a second peripheral contact 294b. The first upper pad 321a may be electrically connected to the external pad 350 through the upper contact plugs 322 and 332 and a second upper conductive pattern 331. Conversely, the second upper pad 321b may not be connected to the second upper conductive patterns 331.

In some implementations, an effective contact structure 280a and preliminary contact structures 280b may have substantially the same structure. However, the effective contact structure 280a may be electrically connected to a circuit component 102 and an external pad 350 through a first lower pad 132a and a first upper pad 321a, and a through-hole via 282b may be in contact with a second lower pad 132b, not connected to other lower conductive patterns, and a second upper pad 321b, not connected to other upper conductive patterns, and may be electrically floating.

Contact structures 280a and 280b may be formed by performing processes of forming lower vias 281a and 281b, through-hole vias 282a, 282b, first peripheral contacts 292a and 292b, and second peripheral contacts 294a and 294b, as illustrated in FIGS. 3, 8, 9, and 10. In some implementations, only a semiconductor mask for forming a lower interconnection structure 110 and an upper interconnection structure 310 may be modified without modifying a semiconductor mask necessary for the above-described processes, thereby selecting an effective contact structure 280a among a plurality of contact structures. Accordingly, time and costs required for manufacturing a memory device may be reduced.

Hereinafter, various implementations of a memory device 10 in which preliminary contact structures 280b are disposed to be adjacent to an effective contact structure 280a are described.

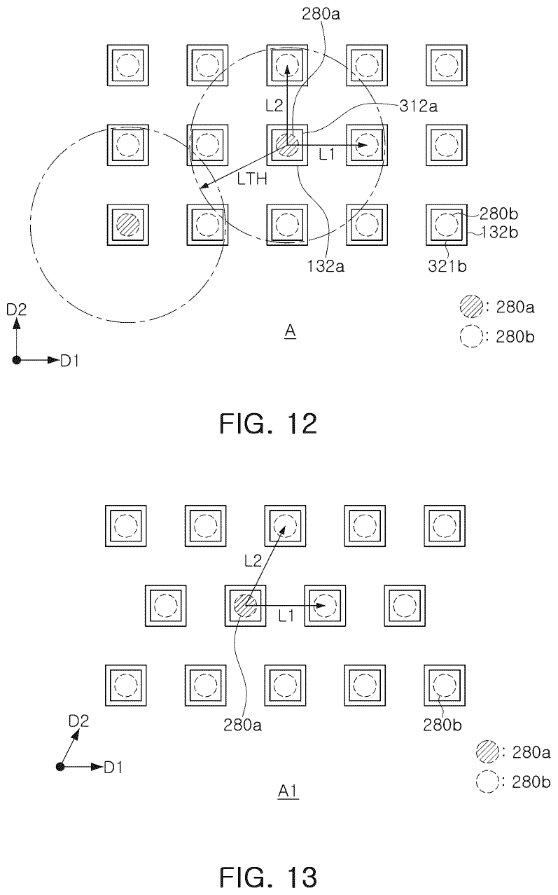

FIGS. 12 to 14 are diagrams illustrating an example of a memory device.

FIG. 12 is an enlarged view of region “A” of FIG. 2.

FIG. 12 illustrates effective contact structures 280a that may be included in a memory device, preliminary contact structures 280b, first upper pads 321a and first lower pads 132a in contact with the effective contact structures 280a, and second upper pads 321b and second lower pads 132b in contact with the preliminary contact structures 280b.

The contact structures 280a and 280b may be arranged in a first direction D1, parallel to an upper surface of a substrate, and a second direction D2, parallel to the upper surface of the substrate and perpendicular to the first direction D1. The contact structures 280a and 280b, arranged in the first direction D1 and the second direction D2, may be referred to as a contact structure array.

As described above, when a plurality of contact structures are disposed to be adjacent to each other, through-via holes for forming the contact structures may be adjacent to each other. When the through-via holes are adjacent to each other, a total area into which etching gas flows may be increased, thereby preventing not-opening defects.

An arrangement relationship between through-via holes capable of preventing not-opening defects may be predetermined. For example, in order to prevent not-opening defects in a target through-via hole, two or more dummy through-via holes or effective through-via holes may be predetermined to be disposed within a predetermined radius LTH from the center of the effective through-via hole. The predetermined radius LTH may be determined relative to a diameter of the through-via hole. For example, the predetermined radius LTH may be determined to be within 10 times or less of a largest diameter of an upper portion of the through-via hole.

In some implementations, in the contact structure array, the contact structures 280a and 280b may be disposed at a first interval L1 in the first direction D1, and may be disposed at a second distance L2 in the second direction D2. For example, the first interval L1 and the second interval L2 may be within the predetermined radius LTH. In some implementations, the first interval L1 and the second interval L2 may be the same or different.

In some implementations, any one of the contact structures, included in the contact structure array, may be selected as the effective contact structure 280a. For example, the contact structure may electrically connect an upper pad and a lower pad in contact with the contact structure to an external pad and a circuit component, respectively, thereby functioning as the effective contact structure 280a.

Referring to FIG. 12, when the effective contact structure 280a is positioned at the center among the contact structures, four contact structures may be disposed within a predetermined radius of the effective contact structure 280a, thereby preventing not-opening defects in the effective contact structure 280a.

Even when the effective contact structure 280a is positioned at the edge among the contact structures, at least two contact structures may be disposed within the predetermined radius of the effective contact structure 280a, thereby also preventing not-opening defects in the effective contact structure 280a.

Similarly, even when some contact structures of the contact structure array are selected as the effective contact structure 280a, at least two contact structures may be disposed around the selected effective contact structures 280a. Accordingly, when a peripheral circuit is designed, an interconnection associated with an upper pad and a lower pad may be modified without modifying the arrangement of the contact structure array, thereby modifying the number and positions of the effective contact structures 280a, and preventing not-opening defects in the effective contact structure 280a.

The present disclosure is not limited to a case in which the first direction D1 and the second direction D2 in which the contact structure array is arranged are orthogonal to each other.

In some implementations, the contact structure array may have various forms of arrangement.

FIG. 13 is a diagram illustrating region “A1” corresponding to region “A” of FIG. 2.

Referring to FIG. 13, a contact structure array disposed in region “A” of FIG. 2 may have an arrangement the same as that illustrated in region “A1” of FIG. 13.

Contact structures 280a and 280b included in the contact structure array may be arranged in a first direction D1 and a second direction D2, parallel to an upper surface of a substrate and intersecting the first direction D1. As illustrated in FIG. 13, the first direction D1 and the second direction D2 may not necessarily be perpendicular to each other.

As described with reference to FIG. 12, even when some contact structures of the contact structure array are selected as the effective contact structure 280a, at least two contact structures may be disposed around the selected effective contact structures 280a.

In FIGS. 12 and 13, a case in which the contact structures 280a and 280b individually have upper pads 321a and 321b and lower pads 132a and 132b has been described as an example, but the present disclosure is not limited thereto.

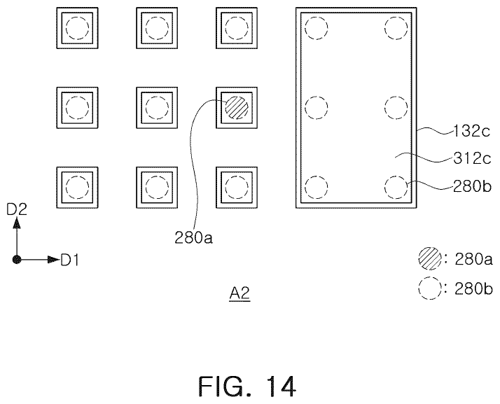

FIG. 14 is a cross-sectional view illustrating an example of a memory device.

Referring to FIG. 14, a contact structure array disposed in region “A” of FIG. 2 may have an arrangement the same as that illustrated in region “A2” of FIG. 14.

The contact structure array may include a plurality of contact structures 280a and 280b arranged in a first direction D1 and a second direction D2, intersecting the first direction D1.

In some implementations, certain contact structures, included in the contact structure array, may be in contact with one shared upper pad 321c and one shared lower pad 132c. The contact structures in contact with the one shared upper pad 321c and the one shared lower pad 132c may be referred to as a contact structure group. In some implementations, contact structures, included in the contact structure group, may be disposed to be adjacent to each other.

Some pads, among external pads included in the memory device, may receive higher power, as compared to other pads. For example, a power pad may receive higher power, as compared to a signal pad.

A contact structure for transmitting power to circuit components may have higher capacity, as compared to other contact structures. For example, a contact structure for transmitting power may have a cross-sectional area larger than that of a contact structure for transmitting a signal.

In some implementations, the contact structure group may be used to supply power or transmit a signal transmitted at relatively high power. For example, upper conductive patterns and lower conductive patterns may be disposed such that the shared upper pad 321c is electrically connected to a power pad and the shared lower pad 132c is electrically connected to a circuit component 102.

When the shared upper pad 321c is connected to the power pad and the shared lower pad 132c is connected to the circuit component 102, the contact structure group may collectively function as an effective contact structure, and may have sufficient capacity for transmitting power. Accordingly, the contact structure group may be used to transmit power to the circuit component 102.

Depending on the design of a peripheral circuit, the shared upper pad 321c and the shared lower pad 132c may not be connected to other conductive patterns, and the contact structure group may be electrically floating. When the contact structure group is disposed as electrically floating preliminary contact structures, the contact structure group may prevent not-opening defects in adjacent contact structures.

Referring to FIGS. 1A to 14, implementations of the present disclosure have been described using, as an example, a case in which a memory device is a cell on peri (COP) memory device. However, the present disclosure is not limited thereto. For example, the memory device may be a memory device having a chip to chip (C2C) structure.

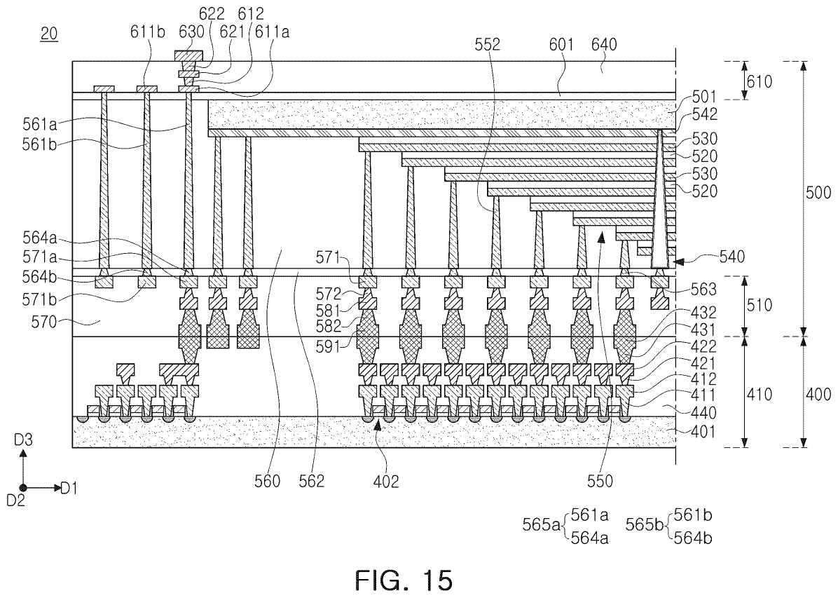

FIG. 15 is a cross-sectional view illustrating an example of a memory device.

Referring to FIG. 15, a memory device 20 may have a C2C structure. The C2C structure may refer to a structure in which at least one upper chip 500 having a cell region and a lower chip 400 having a peripheral circuit region are separately manufactured, and then the at least one upper chip 500 and the lower chip 400 are connected to each other using a bonding method.

For example, the bonding method may refer to a method of electrically or physically connecting a bonding metal pattern, formed on an uppermost metal layer of the upper chip 500, and a bonding metal pattern, formed on an uppermost metal layer of the lower chip 400, to each other. For example, when the bonding metal patterns are formed of copper (Cu), the bonding method may be referred to as a Cu—Cu bonding method. For another example, the bonding metal patterns may be formed of aluminum (Al) or tungsten (W).

In the example of FIG. 15, the memory device 20 may include one upper chip 500 having a cell region, and one lower chip 400 having a peripheral circuit region. The memory device 20 may be manufactured by separately manufacturing the upper chip 500 and the lower chip 400, inverting the upper chip 500, and connecting the upper chip 500 to the lower chip 400 using the bonding method.

Hereinafter, an upper portion and a lower portion of the upper chip 500 may be defined relative to a state in which the upper chip 500 is inverted. In the example of FIG. 15, the upper portion of the upper chip 500 may be defined relative to a third direction D3. For example, a portion of the upper chip 500 in which a second substrate 501 is formed may be referred to as an upper portion, and a portion of the upper chip 500 in which an intermediate interconnection structure 510 is formed may be referred to as a lower portion.

The lower chip 400 may include a first substrate 401, and a plurality of circuit components 402 formed on the first substrate 401. A lower interconnection structure 410, included in a peripheral circuit, may be formed on the first substrate 401 by connecting the plurality of circuit components 402 to each other in series or parallel. For example, the lower interconnection structure 410 may include lower contact plugs 411, 421, and 431 and lower conductive patterns 412, 422, and 432.

The lower contact plugs 411, 421, and 431 and the lower conductive patterns 412, 422, and 432 may be formed of at least one of various conductive materials. For example, the lower contact plugs 411, 421, and 431 and the lower conductive patterns 412, 422, and 432 may be formed of tungsten, copper, or aluminum.

A lower interlayer insulating film 440 may be provided on the first substrate 401 to surround the lower interconnection structure 410. Lower conductive patterns 432, disposed on an uppermost layer of the lower interconnection structure 410, may be exposed to an upper surface of the lower interlayer insulating film 440. The lower interlayer insulating film 440 may include an insulating material such as silicon oxide or silicon nitride.

The upper chip 500 may include the second substrate 501. A cell stack structure 550, including a plurality of memory cells, may be provided on a lower portion of the second substrate 501. In some implementations, the memory device 20 may include a plurality of cell stack structures, but only one cell stack structure 550 is illustrated in FIG. 15.

The cell stack structure 550 may include a channel connection pattern 542, a plurality of gate electrodes 530, and a plurality of insulating patterns 520. The cell stack structure 550 may include the plurality of gate electrodes 530 and the plurality of insulating patterns 520 alternately stacked on an upper portion of channel connection pattern 542 in a direction, perpendicular to a lower surface of the second substrate 501. A channel structure 540 may be provided in a cell region of the cell stack structure 540 to pass through the gate electrodes 530 and the insulating patterns 520.

The channel structure 540 may pass through the gate electrodes 530 and the insulating patterns 520 and extend to the second substrate 501. A sidewall of the channel structure 540 may be in contact with the channel connection pattern 542, and the channel structure 540 may be electrically connected to the second substrate 501 through the channel connection pattern 542.

An edge portion of the cell stack structure 550 may have a staircase shape. A portion of the cell stack structure 550, having a staircase shape, may be referred to as a pad region, and a portion of the cell stack structure 260, not having a staircase shape, may be referred to as a cell region.

The upper chip 500 may include a first intermediate interlayer insulating film 560 covering the cell stack structure 550.

The upper chip 500 may include cell contact plugs 552 passing through the first intermediate interlayer insulating film 560, the cell contact plugs 552 in contact with the pad region of the cell stack structure 550. The cell contact plugs 552 may have different vertical heights.

An upper insulating film 601 may be formed on lower portions of the second substrate 501 and the first intermediate interlayer insulating film 560. For example, the upper insulating film 601 may be stacked on upper portions of the second substrate 501 and the first intermediate interlayer insulating film 560 in a state in which the upper chip 500 is inverted.

An upper metal structure 610 may be formed on the upper insulating film 601. The upper metal structure 610 may include upper conductive patterns 611 and 621, upper contact plugs 612 and 622, and one or more external pads 630. An upper portion of the upper insulating film 601 may include an upper interlayer insulating film 640 covering the upper conductive patterns 611 and 621 and the upper contact plugs 612 and 622.

The external pad 630 may be exposed to an upper surface of the upper interlayer insulating film 640. For example, the external pad 630 may supply externally received power to the memory device 20, may provide an externally received signal to the peripheral circuit, or may externally output a signal generated from the peripheral circuit.

Through-hole vias 561a and 561b may be formed around the cell stack structure 550. In some implementations, the second substrate 501 may not be disposed in a region in which the through-hole vias 561a and 561b are disposed. For example, the through-hole vias 561a and 561b may be formed to pass through the first intermediate interlayer insulating film 560 and the upper insulating film 601, and to be in contact with the first upper conductive pattern 611.

In some implementations, the through-hole vias 561a and 561b may be formed using a process the same as that of the cell contact plugs 552, before the upper chip 500 is bonded to the lower chip 400. For example, the through-hole vias 561a and 561b may be formed to have a diameter gradually decreasing from a lower surface of the first intermediate interlayer insulating film 560 to the upper insulating film 601.

A second intermediate interlayer insulating film 562 may be provided on the lower surface of the first intermediate interlayer insulating film 560. A cell contact 563 and peripheral contacts 564a and 564b may be provided to pass through the second intermediate interlayer insulating film 562. The cell contact 563 may be in contact with an upper surface of the cell contact plug 552, and the peripheral contacts 564a and 564b may be in contact with upper surfaces of the through-hole vias 561a and 561b.

The through-hole vias 561a and 561b and the peripheral contacts 564a and 564b may electrically connect the external pad 630 and the circuit components 402 to each other. The through-hole via 561a and the peripheral contact 564a, and the through-hole via 561b and the peripheral contact 564b may be collectively referred to as contact structures 565a and 565b.

In the example of FIG. 15, a structure may be formed in which one upper contact is vertically stacked on upper portions of the cell contact plug 552 and the through-hole vias 561a and 561b, but in the present disclosure, the number of upper contacts stacked on the upper portions of the cell contact plug 552 and through-hole vias 561a and 561b is not limited thereto.

The intermediate interconnection structure 510 for exchanging a signal with a peripheral circuit region may be provided on a second intermediate interlayer insulating film 562.

The intermediate interconnection structure 510 may include intermediate conductive patterns 571, 581, and 591 and intermediate contact plugs 572 and 582. A third intermediate interlayer insulating film 570 may be formed to surround the intermediate conductive patterns 571, 581, and 591 and the intermediate contact plugs 572 and 582.

Uppermost third intermediate conductive patterns 591, among the intermediate conductive patterns, may be exposed to an upper surface of the third intermediate interlayer insulating film 570, and may be formed in positions overlapping those of uppermost third lower conductive patterns 432, formed on an uppermost portion of the lower chip 400. The third intermediate conductive patterns 591 and the third lower conductive patterns 432 may be connected to each other using a bonding method.

In some implementations, the contact structures 565a and 565b may include an effective contact structure 565a and preliminary contact structures 565b. The effective contact structure 565a and the preliminary contact structures 565b may be disposed to be adjacent to each other.

For example, one or more effective contact structures 565a and one or more preliminary contact structures 565b may be arranged in a first direction D1, parallel to an upper surface of the first substrate 401, and a second direction D2, parallel to the upper surface of the first substrate 401 and intersecting the first direction D1.

The effective contact structure 565a may be in contact with an upper conductive pattern 611a, formed on a lowermost layer of an upper interconnection structure 610, and an intermediate conductive pattern 571a, formed on an uppermost layer of the intermediate interconnection structure 510. The upper conductive pattern 611a and the intermediate conductive pattern 571a may be referred to as a first upper pad and a first lower pad, respectively. A first upper pad 611a may be electrically connected to the external pad 630 through the upper conductive pattern 621 and the upper contact plugs 612 and 622. In addition, a first lower pad 571a may be electrically connected to the circuit components 402 by the intermediate conductive patterns 571, 581, and 591, the intermediate contact plugs 572 and 582, the lower conductive patterns 412, 422, and 432, and the lower contact plugs 411, 421, and 431.

The preliminary contact structure 565b may be in contact with an upper conductive pattern 611b and an intermediate conductive pattern 571b. The upper conductive pattern 611b and the intermediate conductive pattern 571b may be referred to as a second upper pad and a second lower pad, respectively. The second upper pattern 611b and the second lower pad 571b may not be connected to other conductive patterns. That is, the preliminary contact structure 565b may be electrically floating.

In some implementations, in an etching process of forming through-via holes in which the effective contact structure 565a and the preliminary contact structures 565b are to be formed, not-opening defects in the through-via holes may be prevented. Accordingly, defects in the memory device 20 may be prevented, and the memory device 20 may have improved performance.

In addition, the number and positions of effective contact structures 565a, and the preliminary contact structures 565b among contact structures, may be selected by modifying a connection between conductive patterns, and upper pads and lower pads in contact with the contact structures.

In some implementations, one or more preliminary contact structures 565b may include a plurality of preliminary contact structures in contact with one shared upper pad and one shared lower pad. In a similar manner to that described with reference to FIG. 14, interconnections of the upper interconnection structure 610 and the intermediate interconnection structure 510 may be modified, thereby collectively using the plurality of preliminary contact structures as a contact structure group for transmitting power.

In some implementations, the number and positions of effective contact structures 565a may be changed by modifying only semiconductor masks for forming the intermediate interconnection structure 510 and the upper interconnection structure 610, without modifying semiconductor masks for forming a contact structure.

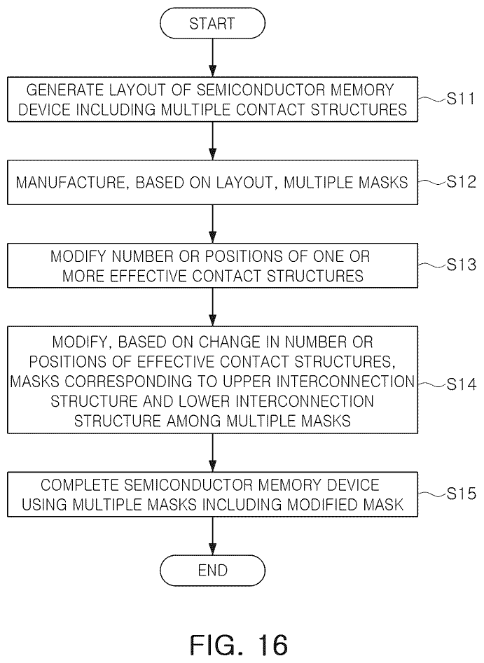

FIG. 16 is a flowchart illustrating an example of a method of manufacturing a memory device.

In operation S11, a layout of a memory device may be generated by performing arrangement and routing. For example, a lower interconnection structure for connecting circuit components, formed on a substrate, to a cell stack structure, an upper interconnection structure for connecting an external pad to the circuit components, and a layout for forming contact structures between the lower interconnection structure and the upper interconnection structure may be generated.

In some implementations, some contact structures, among the contact structures, may be selected as active contact structures electrically connected to an external pad and circuit components, and the other contact structures may be selected as electrically floating preliminary contact structures.

In operation S12, a plurality of masks may be manufactured based on the layout of the memory device. For example, each of the lower interconnection structure, the contact structures, and the upper interconnection structure may have a structure in which a plurality of layers are stacked, and a plurality of masks, having patterns to be formed on the plurality of layers, may be manufactured.

In operation S13, the layout of the memory device may be modified, and the number or positions of one or more effective contact structures may be changed.

In operation S14, masks corresponding to the upper interconnection structure and the lower interconnection structure, among the plurality of masks, may be modified based on a change in the number or positions of the one or more effective contact structures.

In some implementations, a contact structure connected to the external pad and circuit components, among the contact structures, may be changed by modifying the masks corresponding to the upper interconnection structure and the lower interconnection structure. That is, the number and positions of effective contact structures may be changed even without modifying the plurality of masks for forming the contact structures.

In operation S15, the memory device may be completed using the plurality of masks including the modified masks. For example, the memory device in which the circuit components, the lower interconnection structure, the cell stack structure, the contact structures, and the upper interconnection structure are stacked on the substrate may be formed using the plurality of masks.

In some implementations, the number and positions of effective contact structures may be changed even without modifying the plurality of masks for forming the contact structures, thereby reducing time and costs required for manufacturing a semiconductor device.

In some implementations, a memory device may have a plurality of contact structures respectively passing through an interlayer insulating film, the plurality of contact structures respectively in contact with an upper interconnection and a lower interconnection. Only upper conductive patterns and lower conductive patterns may be modified, such that the number and positions of effective contact structures electrically connected to circuit components and an external pad, among the plurality of contact structures, may be easily selected. As a result, time and costs required for manufacturing the memory device may be reduced.

In the memory device, electrically floating preliminary contact structures, among the plurality of contact structures, may be disposed to be adjacent to the effective contact structures, thereby preventing not-opening defects in the effective contact structures.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination.

Moreover, although features may be described above as acting in certain combinations, one or more features from a combination can in some cases be excised from the combination, and the combination may be directed to a subcombination or variation of a subcombination.

While implementations have been shown and described above, it will be apparent to those skilled in the art that modifications and variations could be made without departing from the scope of the present disclosure as defined by the appended claims.

1. A memory device comprising:
a lower interconnection structure on a substrate, the lower interconnection structure including a plurality of circuit components and a plurality of lower conductive patterns;
a cell stack structure on the lower interconnection structure, the cell stack structure including a plurality of gate electrodes stacked and spaced apart from each other in a vertical direction, the vertical direction perpendicular to an upper surface of the substrate;
an interlayer insulating layer covering the cell stack structure;
an upper interconnection structure on the interlayer insulating layer, the upper interconnection structure including a plurality of upper conductive patterns and one or more external pads;
one or more effective contact structures respectively passing through the interlayer insulating layer, the one or more effective contact structures respectively having an upper surface and a lower surface, the upper surface of an effective contact structure being in contact with a first upper pad electrically connected to an external pad of the one or more external pads, and the lower surface of the effective contact structure being in contact with a first lower pad electrically connected to the plurality of circuit components; and
one or more preliminary contact structures respectively passing through the interlayer insulating layer, the one or more preliminary contact structures respectively having an upper surface and a lower surface, the upper surface of a preliminary contact structure being in contact with a second upper pad, and the lower surface of the preliminary contact structure being in contact with a second lower pad,
wherein the one or more preliminary contact structures are electrically floating.

2. The memory device of claim 1, wherein
the one or more preliminary contact structures include a plurality of first preliminary contact structures, and
the plurality of first preliminary contact structures are adjacent to the one or more effective contact structures, or the plurality of first preliminary contact structures are adjacent to each other.

3. The memory device of claim 2, wherein among the plurality of first preliminary contact structures and the one or more effective contact structures, a plurality of contact structures that are adjacent to each other are spaced apart from each other by a distance, the distance being 10 times or less of a largest diameter of a through-via hole in which the plurality of adjacent contact structures are formed.

4. The memory device of claim 1, wherein the one or more effective contact structures and the one or more preliminary contact structures are arranged in a first direction and a second direction, the first direction being parallel to the upper surface of the substrate, and the second direction being parallel to the upper surface of the substrate and intersecting the first direction.

5. The memory device of claim 4, wherein the first direction and the second direction are orthogonal to each other.

6. The memory device of claim 4, wherein the one or more effective contact structures and the one or more preliminary contact structures are arranged at a predetermined first interval in the first direction, and are arranged at a predetermined second interval in the second direction.

7. The memory device of claim 6, wherein the first interval and the second interval are the same.

8. The memory device of claim 1, wherein the one or more preliminary contact structures include a plurality of second preliminary contact structures, the plurality of second preliminary contact structures sharing one second upper pad and one second lower pad.

9. The memory device of claim 8, wherein the plurality of second preliminary contact structures are adjacent to each other.

10. The memory device of claim 1, wherein
the one or more effective contact structures include a plurality of first effective contact structures, the plurality of first effective contact structures sharing one first upper pad and one first lower pad, and
the first effective contact structures are electrically connected to a power pad of the one or more external pads.

11. The memory device of claim 1, wherein the one or more effective contact structures and the one or more preliminary contact structures have the same shape.

12. The memory device of claim 1, wherein each contact structure of the one or more effective contact structures and the one or more preliminary contact structures includes a through-hole via.

13. The memory device of claim 1, wherein
the first upper pad and the second upper pad are included in a lowermost conductive pattern among the plurality of upper conductive patterns, and
the first lower pad and the second lower pad are included in an uppermost conductive pattern among the plurality of lower conductive patterns.

14. A memory device comprising:
a lower interconnection structure on a substrate, the lower interconnection structure including a plurality of circuit components and a plurality of lower conductive patterns;
a cell stack structure on the lower interconnection structure, the cell stack structure including a plurality of gate electrodes stacked spaced apart from each other in a vertical direction, the vertical direction perpendicular to an upper surface of the substrate;
an interlayer insulating layer covering the cell stack structure;
an upper interconnection structure on the interlayer insulating layer, the upper interconnection structure including a plurality of upper conductive patterns and an external pad;
an effective contact structure passing through the interlayer insulating layer, the effective contact structure having an upper surface and a lower surface, the upper surface of the effective contact structure being in contact with a first upper pad electrically connected to the external pad, and the lower surface of the effective contact structure being in contact with a first lower pad electrically connected to the circuit components; and
one or more preliminary contact structures respectively passing through the interlayer insulating layer, the one or more preliminary contact structures respectively having a structure same as the effective contact structure,
wherein the one or more preliminary contact structures are electrically floating.

15. A memory device comprising:
a lower chip including a first substrate, a plurality of circuit components on the first substrate, and a lower interconnection structure electrically connected to the plurality of circuit components; and
an upper chip on the lower chip, the upper chip including a second substrate, an upper interconnection structure on an upper surface of the second substrate, an external pad connected to the upper interconnection structure, a cell stack structure including a plurality of gate electrodes stacked and spaced apart from each other in a first direction, the first direction perpendicular to a lower surface of the second substrate, an interlayer insulating layer surrounding a lower surface and a side surface of the cell stack structure, an intermediate interconnection structure below the interlayer insulating layer and bonded to the lower interconnection structure, one or more effective contact structures respectively passing through the interlayer insulating layer, and one or more preliminary contact structures respectively passing through the interlayer insulating layer, the one or more effective contact structures respectively having an upper surface and a lower surface, the upper surface of an effective contact structure being in contact with a first upper pad electrically connected to the external pad, the lower surface of the effective contact structure being in contact with a first lower pad electrically connected to the circuit components, the one or more preliminary contact structures respectively having an upper surface and a lower surface, the upper surface of a preliminary contact structure being in contact with a second upper pad, and the lower surface of the preliminary contact structure being in contact with a second lower pad,
wherein the one or more preliminary contact structures are electrically floating.

16. The memory device of claim 15, wherein the one or more effective contact structures and the one or more preliminary contact structures are arranged in a first direction and a second direction, the first direction being parallel to an upper surface of the first substrate, and the second direction being parallel to the upper surface of the first substrate and intersecting the first direction.

17. The memory device of claim 15, wherein the one or more preliminary contact structures include a plurality of second preliminary contact structures, the plurality of second preliminary contact structures sharing one second upper pad and one second lower pad.

18. The memory device of claim 15, wherein
the first upper pad and the second upper pad are included in conductive patterns of a lowermost layer of the upper interconnection structure, and
the first lower pad and the second lower pad are included in conductive patterns of an uppermost layer of the intermediate interconnection structure.

19. The memory device of claim 15, wherein the one or more effective contact structures and the one or more preliminary contact structures have a diameter gradually decreasing in a direction from the first substrate to the second substrate.

20. The memory device of claim 15, wherein the one or more effective contact structures and the one or more preliminary contact structures pass through the interlayer insulating layer around the second substrate.

21. (canceled)
